(19) United States
(12) Patent Application Publication
(10) Pub. No.: US 2010/0163916 A1
(43) Pub. Date: Jul. 1, 2010

(54) FULL-COVER LIGHT-EMITTING DIODE LIGHT BAR AND METHOD FOR MANUFACTURING THE SAME

(76) Inventor: Chin-Chih Chiang, Chung Ho City (TW)

Correspondence Address: HDLS Patent & Trademark Services, P.O. BOX 220746, CHANTILLY, VA, 20153-0746, US

(21) Appl. No.: 12/431,115

(22) Filed: Apr. 28, 2009

(30) Foreign Application Priority Data
Dec. 31, 2008 (TW) 097151547

(51) Int. Cl. H01L 33/00; H01L 21/50

(52) U.S. Cl. 257/99; 438/26; 257/E33.056; 257/E21.499

(57) ABSTRACT

In a full-cover light-emitting diode light bar that can withstand a large bending deformation, a first lead and a second lead are juxtaposed with a distance. An insulating layer having a slot is formed on the first lead and the second lead via a hot pressing process. A crystal-receiving section of the first lead is displayed in the slot, and a connecting section of the second lead is displayed in the slot. A light-emitting diode crystal has a first electrode and a second electrode. Then, the light-emitting diode crystal is disposed in the slot with the first electrode being electrically fixed to the crystal-receiving section. The second electrode of the light-emitting diode crystal is electrically connected to the connecting section via a metallic lead. A light-transmitting body is used to seal the slot. Via the above process, a full-cover light-emitting diode light bar is formed.

### BACKGROUND OF THE INVENTION

1. Field of the Invention

The present invention relates to a light-emitting device, and in particular to a parallel light-emitting diode light bar.

2. Description of Prior Art

Since Light Emitting Diode (LED) has many advantages such as low electricity consumption, long lifetime, small volume, quick response or the like, it is used in various light-emitting devices to replace the traditional bulbs. For example, the LED can be used in decorative light bars.

With regard to the patent documents in which a LED is used as a light-emitting element, Taiwan Patent Publication No. 558622 discloses an adhesive light bar and a method for manufacturing the same. According to the disclosure of this patent document, a lower adhesive layer and an upper adhesive layer are used to bind a conductive unit there between. Then, a connecting process is performed, whereby a connecting lead is electrically connected to a light source unit and the conductive unit. Finally, a packaging process is performed, whereby the light source unit and the connecting lead can be covered to form a light bar.

However, in the above-mentioned patent document, the conductive unit is bound between the upper and lower adhesive layers. When the light bar is bent substantially, the upper and lower adhesive layers may be detached from each other due to the bending deformation. At this time, the conductive unit bound between these adhesive layers may be loosened and moved, which further results in the breakage of tiny connecting leads. As a result, the light source unit is damaged and the aesthetic feeling of the light bar is upset when emitting light is deteriorated.

Therefore, in order to overcome the above problems, the present Inventor proposes a reasonable and novel structure based on his delicate researches and expert experiments.

### SUMMARY OF THE INVENTION

The present invention is to provide a full-cover light-emitting diode light bar that can withstand a large bending deformation.

The present invention is to provide a full-cover light-emitting diode light bar having a first lead and a second lead that are juxtaposed with a distance. An insulating layer having a slot is formed on the first lead and the second lead via a hot pressing process. A crystal-receiving section of the first lead is displayed in the slot, and a connecting section of the second lead is displayed in the slot. Further, a light-emitting diode crystal having a first electrode and a second electrode is disposed in the slot with the first electrode being electrically fixed to the crystal-receiving section. The second electrode is electrically connected to the connecting section via a metallic lead. Finally, a light-transmitting body is used to seal the slot. In this way, a full-cover light-emitting diode light bar can be formed.

In comparison with prior art, the present invention has advantageous features as follows. Since the insulating layer is formed by means of a hot pressing process so as to cover the first lead and the second lead, the insulating layer can still cover the first lead and the second lead firmly without any displacement even the light-emitting diode light bar is subjected to a large binding deformation. Thus, the breakage of the metallic lead connecting the light-emitting diode crystal and the second lead caused by the displacement of the insulating layer as well as the damage of the light-emitting diode crystal can be prevented. In this way, the aesthetic feeling of the light bar when emitting light can be maintained, so that the practicability of the present invention can be increased.

### BRIEF DESCRIPTION OF THE DRAWINGS

FIG. 1 is a perspective view showing the external appearance of the present invention;

FIG. 2 is a schematic view showing the first lead and the second lead of the present invention;

FIG. 3 is a schematic view showing the insulating layer being thermally pressed on the first lead and the second lead in accordance with the present invention;

FIG. 4 is a schematic view showing the first electrode being electrically fixed to a crystal-receiving section in accordance with the present invention;

FIG. 5 is a schematic view showing the metallic lead being electrically connected to the second electrode and the connecting section in accordance with the present invention;

FIG. 6 is a schematic view showing the light-transmitting body of the present invention for sealing the slot;

FIG. 7 is a cross-sectional view taken along the line 7-7 in FIG. 6; and

FIG. 8 is a flow chart showing the steps of the method for manufacturing the present invention.

### DETAILED DESCRIPTION OF THE INVENTION

The characteristics and technical contents of the present invention will be explained with reference to the accompanying drawings. However, the drawings are illustrative only but not used to limit the present invention.

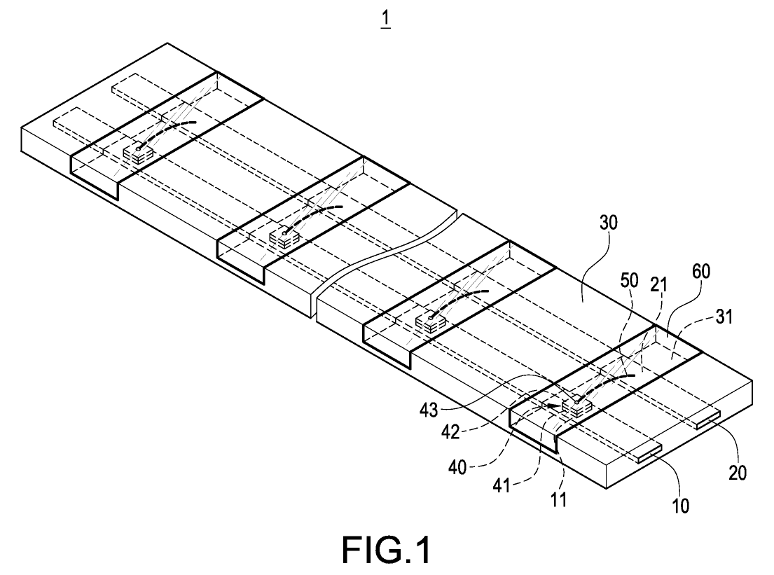

Please refer to FIG. 1, which is a perspective view showing the external appearance of the full-cover light-emitting diode light bar of the present invention. The present invention provides a full-cover light-emitting diode light bar 1, which includes a first lead 10 and a second lead 20. The second lead 20 is separated from the first lead 10 by a distance. Further, via a hot pressing process, an insulating layer 30 is formed. The insulating layer 30 covers the first lead 10 and the second lead 20 and is formed with a slot 31. The insulating layer is made of plastic materials. A crystal-receiving section 11 of the first lead 10 is displayed in the slot 31, and a connecting section 21 of the second lead 20 is displayed in the slot 31.

A light-emitting diode crystal 40 is disposed in the slot 31. The light-emitting diode crystal 40 has a first electrode 41 and a second electrode 42. The first electrode 41 is electrically fixed to the crystal-receiving section 11. The second electrode 42 and the connecting section 21 are connected to each other via a metallic lead 50. The metallic lead 50 can be a golden wire or other alternative metallic wires for wiring. In the present embodiment, the second electrode 42 is provided with a metallic pad 43. The metallic lead 50 is electrically connected to the metallic pad 43 and the connecting section 21.

After completing the electrical connection of the light-emitting diode crystal 40, a light-transmitting body 60 is used to seal the slot 31. The light-transmitting body 60 is made of transparent epoxy resin or other rubber, which can be used to cover the light-emitting diode crystal 40, the metallic lead 50, the crystal-receiving section 11 and the connecting section 21.

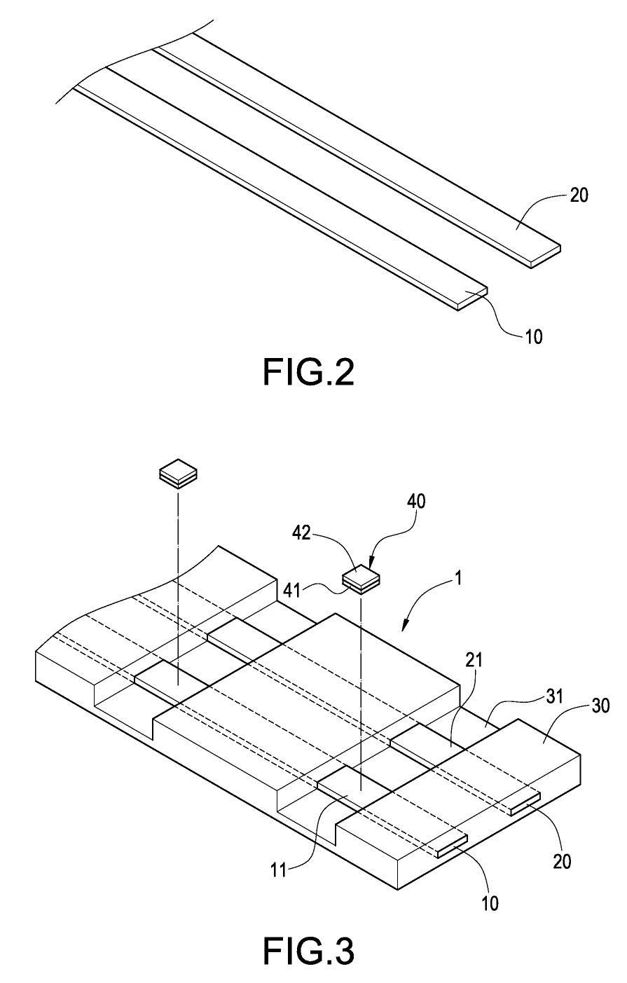

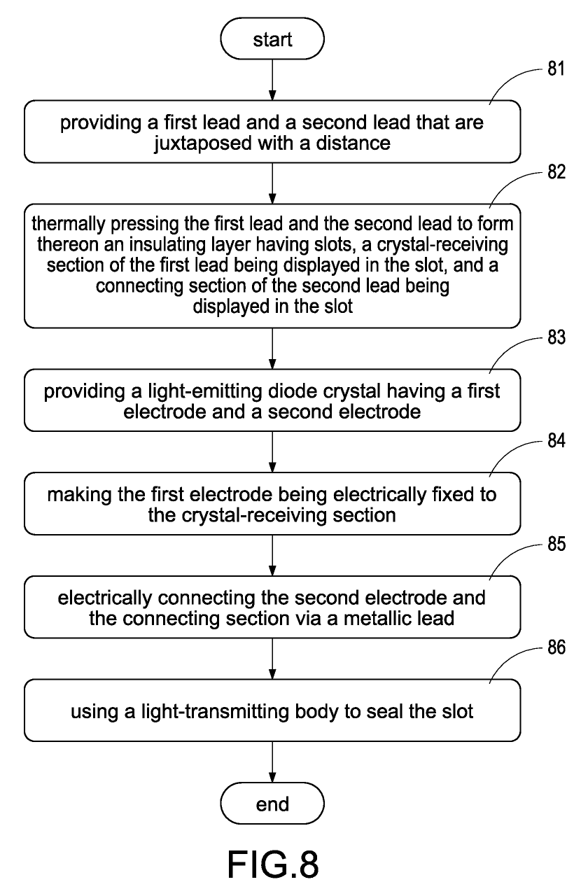

Please refer to FIGS. 2 to 7, which show the manufacturing of the full-cover light-emitting diode light bar of the present invention. Please also refer to FIG. 8, which is a flow chart showing the steps of the method for manufacturing the full-cover light-emitting diode light bar of the present invention. First, as shown in FIG. 2, a first lead 10 and a second lead 20 that are juxtaposed with a distance are provided (step 81). Then, as shown in FIG. 3, via a hot pressing process, an insulating layer 30 having a slot 31 is formed on the first lead 10 and the second lead 20 (step 82). A crystal-receiving section 11 of the first lead 10 and a connecting section 21 of the second lead 20 are displayed in the slot 31.

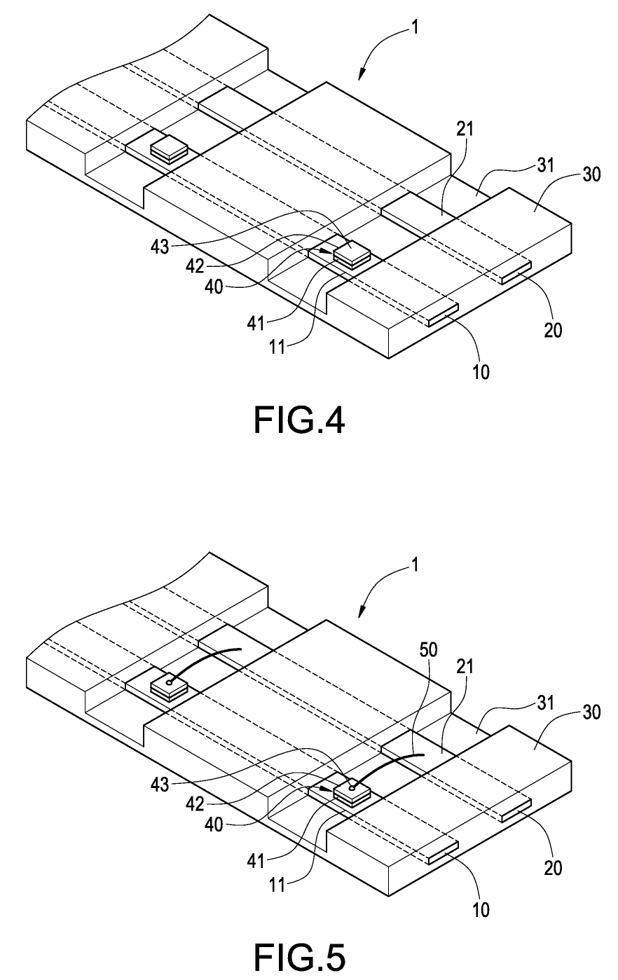

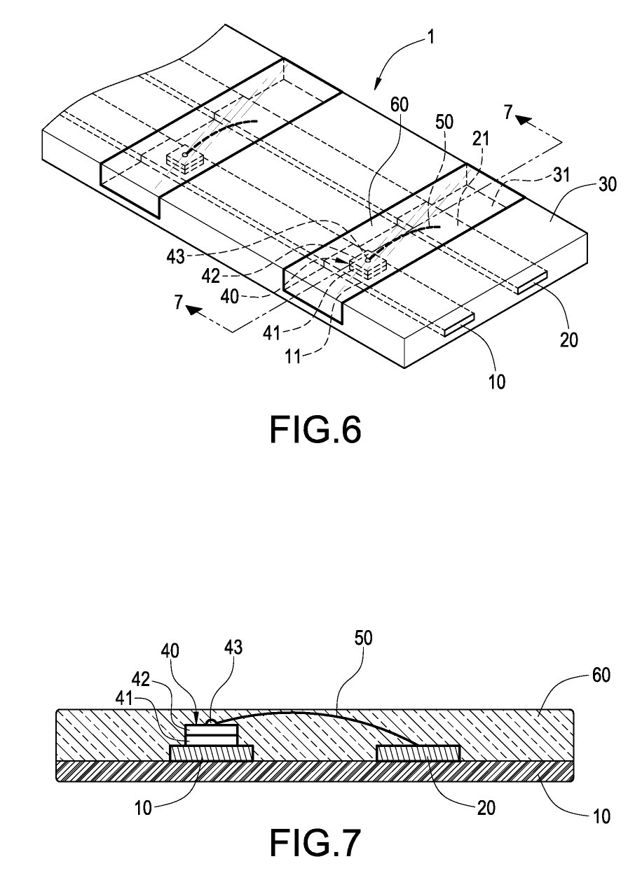

Further, a light-emitting diode crystal 40 is provided (step 83). The light-emitting diode crystal 40 has a first electrode 41 and a second electrode 42. The second electrode 42 is provided with a metallic pad 42. As shown in FIG. 4, the light-emitting diode crystal 40 is disposed in the slot 31 with the first electrode 41 being electrically connected to the crystal-receiving section 11 (step 84). As shown in FIG. 5, a metallic lead 50 is electrically connected to the second electrode 42 and the connecting section 21 (step 85). Finally, as shown in FIG. 6, a light-transmitting body 60 is used to seal the slot 31, thereby covering the light-emitting diode crystal 40, the metallic lead 50, the crystal-receiving section 11 and the connecting section 21 in the slot 31 (step 86).

Please refer to FIG. 7, which is an assembled cross-sectional view of the present invention. As shown in the figure, the light-transmitting body 60 covers the light-emitting diode crystal 40 and the metallic lead 50 completely. When a wiring process is performed, the metallic lead 50 will be positioned in a level higher than that of the surface of the light-emitting diode crystal 40. Thus, the depth of the slot 31 of the insulating layer 30 and the height of the light-transmitting body 60 must be taken into consideration carefully.

Although the present invention has been described with reference to the foregoing preferred embodiments, it will be understood that the invention is not limited to the details thereof. Various equivalent variations and modifications can still occur to those skilled in this art in view of the teachings of the present invention. Thus, all such variations and equivalent modifications are also embraced within the scope of the invention as defined in the appended claims.

What is claimed is:

1. A method for manufacturing a full-cover light-emitting diode light bar, comprising the steps of:
(a) providing a first lead and a second lead that are juxtaposed with a distance;
(b) thermally pressing the first lead and the second lead to form thereon an insulating layer having a slot, a crystal-receiving section of the first lead being displayed in the slot, and a connecting section of the second lead being displayed in the slot;
(c) providing a light-emitting diode crystal having a first electrode and a second electrode;
(d) disposing the light-emitting diode crystal in the slot with the first electrode being electrically fixed to the crystal-receiving section;
(e) electrically connecting the second electrode of the light-emitting diode crystal to the connecting section via a metallic lead; and
(f) using a light-transmitting body to seal the slot so as to cover the light-emitting diode crystal, the metallic lead, the crystal-receiving section and the connecting section.

2. The method according to claim 1, wherein the step (d) is followed by an additional step (d′) of forming a metallic pad on the second electrode of the light-emitting diode crystal.

3. The method according to claim 2, wherein the metallic lead is electrically connected to the metallic pad and the connecting section.

4. A full-cover light-emitting diode light bar, comprising:
a first lead;
a second lead separated from the first lead by a distance;
an insulating layer covering the first lead and the second lead via a hot pressing process,
the insulating layer being formed with a slot, a crystal-receiving section of the first lead being displayed in the slot, and a connecting section of the second lead being displayed in the slot;
a light-emitting diode crystal having a first electrode and a second electrode, the light-emitting diode crystal being disposed in the slot with the first electrode electrically fixed on the crystal-receiving section;
a metallic lead electrically connected to the second electrode and the connecting section; and
a light-transmitting body for sealing the slot and covering the light-emitting diode crystal, the metallic lead, the crystal-receiving section and the connecting section.

5. The full-cover light-emitting diode light bar according to claim 4, wherein the insulating layer is made of plastic materials.

6. The full-cover light-emitting diode light bar according to claim 4, wherein the metallic lead is a golden wire.

7. The full-cover light-emitting diode light bar according to claim 4, wherein the second electrode further comprises a metallic pad, the metallic lead is electrically connected to the metallic pad and the connecting section.

8. The full-cover light-emitting diode light bar according to claim 4, wherein the light-transmitting body is made of epoxy resin.
